(19) United States
(12) Patent Application Publication
(10) Pub. No.: US 2006/0163594 A1
(43) Pub. Date: Jul. 27, 2006

(54) High electron mobility devices

(76) Inventor: Jan Kuzmik, Bratislava (SK)

Correspondence Address: IVAN DAVID ZITKOVSKY PH.D PC, 5 MILITIA DRIVE, LEXINGTON, MA, 02421, US

(21) Appl. No.: 11/372,559

(22) Filed: Mar. 9, 2006

Related U.S. Application Data
(63) Continuation of application No. 10/772,673, filed on Feb. 5, 2004, now abandoned.
Application No. 10/772,673 is a continuation of application No. PCT/SK02/00018, filed on Jul. 15, 2002.
(60) Provisional application No. 60/310,546, filed on Aug. 7, 2001.

(51) Int. Cl. H01L 33/00

(52) U.S. Cl. 257/94

(57) ABSTRACT

The present invention is directed to high frequency, high power or low noise devices such as low noise amplifiers, amplifiers operating at frequencies in the range of 1 GHz up to 400 GHz, radars, portable phones, satellite broadcasting or communication systems, or other devices and systems that use high electron mobility transistors, also called hetero-structure field-effect transistors. A high electron mobility transistor (HEMT) includes a substrate, a quantum well structure and electrodes. The high electron mobility transistor has a polarization-induced charge of high density. Preferably, the quantum well structure includes an AlN buffer layer, an un-doped GaN layer, and an un-doped InAlN layer.

This application is a continuation of U.S. application Ser. No. 10/772,673, filed on Feb. 5, 2004, which is a continuation of PCT Application PCT/SK02/00018, filed Jul. 15, 2002, which claims priority from U.S. Provisional Application 60/310,546 filed Aug. 7, 2001.

### 1. FIELD OF THE INVENTION

The present invention relates to high electron mobility transistors (HEMTs), also called hetero-structure field-effect transistors (HFETs), having polarization-induced charge of high density.

### 2. DESCRIPTION OF THE RELATED ART

High electron mobility transistors (HEMT) are field effect devices that use high mobility carriers. Most conventional semiconductor devices use semiconductor layers doped with n-type impurities to generate electrons (or p-type impurities to generate holes) as carriers. However, the impurities cause the electrons (or holes) to slow down because they alter periodicity of the lattice structure, i.e., they form defects that cause collisions. On the other hand, HEMTs provide for carriers with higher mean free paths and thus higher frequency of operation.

The hetero-interface HEMTs are usually made of two materials: a wide band gap barrier layer (i.e., the AlGaAs layer) and a channel layer (i.e., the GaAs layer). An un-doped GaAs layer is located on a semi-insulating GaAs substrate and acts as a channel layer. Located on the un-doped GaAs layer is an un-doped AlₓGa₁₋ₓAs layer and a doped AlₓGa₁₋ₓAs layer, which is an electron-supplying layer. The HEMT also includes a gate electrode located between a source electrode and a drain electrode, all located above an un-doped AlₓGa₁₋ₓAs layer.

As mentioned above, the wide band gap AlGaAs layer is in contact with GaAs layer. Due to conduction band discontinuity ΔE_{C} between these two layers and existence of the electric field at the interface, there is electron gas formed in the un-doped GaAs layer along the interface with the AlₓGa₁₋ₓAs layer. The electron gas forming an electron gas layer (or volume) is formed in the un-doped GaAs layer closed to the interface, wherein the electrons generated in n-type AlGaAs layer transfer across the AlₓGa₁₋ₓAs layer and are located completely in the GaAs layer. Since the GaAs layer has a substantially “perfect” structure without doped impurities, these electrons have a high mobility, and can move while undergoing much less collisions. Typically, the maximum available electron density for single modulation-doped quantum wells is about 4×10¹² cm⁻².

The un-doped AlₓGa₁₋ₓAs layer increases the breakdown voltage of the HEMT. The Al-content x of the layer, represented in the composition AlₓGa₁₋ₓAs, is desired to have a relatively large value to increase the sheet density of the two-dimensional electron gas located in GaAs channel layer. In general, electrons generated in n-type AlGaAs layer are generally in the range of about x=0.2 to about 0.3.

FIG. 2 shows diagrammatically a band gap diagram of HEMT 2 under thermal equilibrium. At the GaAs/AlGaAs interface, the conduction band E_{C} is located below the Fermi level E_{F}, enabling formation of a two dimensional electron gas (2DEG). This two-dimensional electron gas has a Gaussian electron density distribution. Under a biased state this electron density distribution spreads out. Under the condition of thermal equilibrium, the electron-supplying layer 18 is entirely depleted. When a positive bias voltage is applied to gate electrode 8, an electrically neutral region appears in layer 18 and grows with an increase of the biased voltage. Thus, the electron density of the n⁺-type AlₓGa₁₋ₓAs layer 18 increases with the gate voltage. The mobility of the electrons in the electron-supplying layer 18 (n⁺-type AlₓGa₁₋ₓAs) is lower than that in GaAs channel layer 14 as explained above. On the other hand, negative bias applied to the gate depletes the electron gas 15 until no current will flow.

There is still a need for HEMTs with high electron charge density to obtain even better device performance.

### SUMMARY OF THE INVENTION

The present invention relates to high electron mobility transistors (HEMTs), also called hetero-structure field-effect transistors (HFETs) having polarization-induced charge of high density. The present invention also relates to a method of fabricating such HEMTs (or HFETs). The present invention also relates to high frequency, high power or low noise devices such as low noise amplifiers, amplifiers operating at frequencies in the range of 1 GHz up to 400 GHz, radars, portable phones, satellite broadcasting or communication systems, or other systems using the described HEMTs.

According to one aspect, a HEMT (or HFET) includes a substrate; and a quantum well layered structure including at least a barrier layer and a channel providing the total 2DEG density of above about nₜₒₜₐₗ=1.1×10¹³ cm⁻².

According to another aspect, a HEMT (or HFET) includes a substrate; and a layered quantum well structure, made of III-nitrides, including at least a barrier layer and a channel layer wherein barrier layer contains InₓAl₁₋ₓN, where x is in the range of about 0≦x≦0.30.

According to yet another aspect, a III-nitrides HEMT (or HFET) includes a substrate and a cation-polarity layered structure including at least a barrier layer and a channel layer. Due to high polarization fields in the III-nitrides QW structure, a high-density electron charge is accumulated at the barrier/channel layer QW hetero-interface. The current transport is facilitated through the QW 2DEG. Preferably, the QW 2DEG density is increased by the use of a barrier layer containing InₓAl₁₋ₓN (wherein x is in the range of about 0≦x≦0.30) lattice matched or strained to the bottom layer.

Preferably, the channel layer includes GaN and the barrier layer includes lattice matched In_{0.17}Al_{0.83}N. Alternatively, the barrier layer includes InₓAl₁₋ₓN, wherein x is in the range of about 0≦x≦0.17.

According to another embodiment, a III-nitrides HEMT (or HFET) includes a barrier layer having InₓAl₁₋ₓN, wherein x is in the range of about 0.17<x≦0.25, and a channel layer having GaN. The quantum well structure includes several unique properties that made the III-nitrides HEMT suitable for high power, high frequency and high temperature applications.

According to yet another embodiment, a III-nitrides HEMT (or HFET) includes a barrier layer having In_{0.17}Al_{0.83}N, and a channel layer having In_{y}Ga_{1-y}N, wherein y is in the range of about 0<y≦1. Alternatively, the barrier layer includes InₓAl₁₋ₓN, wherein x is in the range of about 0≦x<0.17 and the channel layer includes In_{y}Ga_{1-y}N, wherein y is in the range of about 0<y≦1. Alternatively, the barrier layer includes InₓAl₁₋ₓN, wherein x is in the range of about 0.17<x≦0.30, and the channel layer includes In_{y}Ga_{1-y}N, wherein y is in the range of about 0<y≦1.

These HEMTs use a InAlN barrier layer (which replaces a AlGaN layer) thus forming a InAlN/(In)GaN QW structure (instead of a prior art AlGaN/GaN QW structure) even though this approach is counter-intuitive and at this time InAlN is more difficult to grow on GaN that AlGaN.

According to yet another aspect, a HEMT (or HFETs) includes a substrate; and a quantum well layered structure including at least a barrier layer and a channel providing the total 2DEG density of above about nₜₒₜₐₗ=1.1×10¹³ cm⁻². Preferably, the channel layer provides a polarization-induced charge.

According to yet another aspect, a HEMT (or HFETs) includes a substrate; and a quantum well layered structure including at least a barrier layer and a channel providing a 2DEG of high density due the polarization phenomena and impurity doping of a layer included in the quantum well structure.

Preferably, in the above devices, high drain currents, power capabilities or low noise properties result from a high QW polarization-induced 2DEG alone or in combination with a doped layer providing charge carriers.

According to yet another aspect, a high electron mobility transistor (HEMT), also called a hetero-structure field-effect transistor (HFETs) is fabricated by a method including providing a substrate; and fabricating a layered QW structure including at least a barrier layer and a channel layer providing the total two dimensional electron gas density of above nₜₒₜₐₗ=1.1×10¹³ cm⁻².

According to yet another aspect, a HEMT (or HFETs) is fabricated by a method including providing a substrate; and fabricating a layered QW structure including at least a barrier layer and a channel layer wherein barrier layer includes InₓAl₁₋ₓN where 0≦x≦0.30.

According to yet another aspect, a HEMT (or HFETs) is used a communications system comprising: (a) fabricating the hetero-interface field effect transistor using the steps of: providing a substrate; and fabricating a layered QW structure including at least a barrier layer and a channel layer wherein barrier layer includes InₓAl₁₋ₓN where 0≦x≦0.30; and (b) using the fabricated hetero-interface field effect transistor in the communications system.

According to yet another aspect, a HEMT (or HFETs) is used in an electronic device comprising an electronic circuit including a hetero-interface field effect transistor using having a substrate; and a layered quantum well structure including at least a barrier layer and a channel layer providing a polarization-induced charge.

In general, an electronic device utilizing a hetero-interface field effect transistor includes a substrate, and a layered quantum well structure including at least a barrier layer and a channel layer providing a polarization-induced charge. Preferred embodiments of this electronic device may include any one of the following: A portable telephone phone comprising the hetero-interface field effect transistor. A communication system comprises the hetero-interface field effect transistor. A low noise amplifier comprises the hetero-interface field effect transistor. A radar system comprises the hetero-interface field effect transistor. A sensor comprises the hetero-interface field effect transistor of claim. An intermediate frequency amplifier comprises the hetero-interface field effect transistor. A direct broadcast satellite system comprises the hetero-interface field effect transistor. A satelite communication system comprises the hetero-interface field effect transistor.

### BRIEF DESCRIPTION OF THE DRAWINGS

FIG. 1 illustrates an AlGaAs/GaAs HEMT according to prior art.

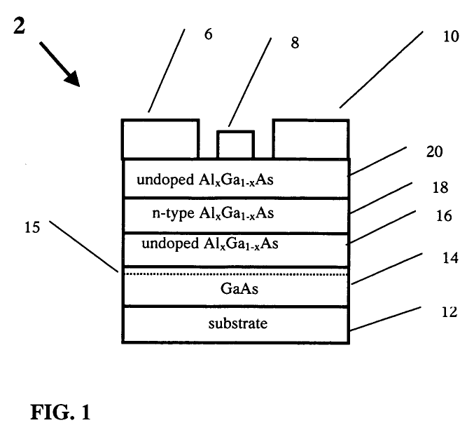

FIG. 2 is a band gap diagram of the HEMT shown in FIG. 1.

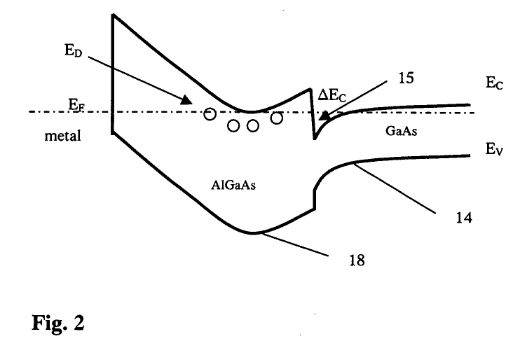

FIG. 3 is a cross-sectional view of an In_{0.17}Al_{0.83}N/GaN HEMT according to a first preferred embodiment.

FIG. 3A is a band gap diagram of an In_{0.17}Al_{0.83}N/GaN quantum well used in the HEMT shown in FIG. 3.

FIG. 3B is a band gap diagram of an In_{0.25}Al_{0.75}N/GaN quantum well.

FIG. 4 is a cross-sectional view of an In_{0.17}Al_{0.83}N/In_{0.10}Ga_{0.90}N HEMT according to a second embodiment.

FIG. 4A is a band gap diagram of an In_{0.17}Al_{0.83}N/In_{0.10}Ga_{0.90}N quantum well used in the HEMT shown in FIG. 4.

FIG. 4B is a band gap diagram of an In_{0.15}Al_{0.85}N/In_{0.1}Ga_{0.9}N quantum well used in an In_{0.15}Al_{0.85}N/In_{0.1}Ga_{0.9}N HEMT.

FIG. 4C is a band gap diagram of the In_{0.30}Al_{0.70}N/In_{0.1}Ga_{0.9}N quantum well used in an In0.3Al_{0.7}N/In_{0.1}Ga_{0.9}N HEMT.

FIG. 5 is a graph of calculated drain current and transconductance characteristics of the In_{0.17}Al_{0.83}N/GaN and In_{0.17}Al_{0.83}N/In_{0.10}Ga_{0.90}N HEMTs, respectively, in comparison to the AlGaN/GaN HEMT.

FIG. 5A is a graph of calculated drain current and transconductance characteristics of the In_{0.25}Al_{0.75}N/GaN, In_{0.15}Al_{0.85}N/In_{0.10}Ga_{0.9}N, and In_{0.30}Al_{0.70}N/In_{0.10}Ga_{0.9}N HEMTs, respectively, in comparison to the AlGaN/GaN HEMT.

FIG. 6 illustrates for III-nitrides the dependence of energy gap (ΔE_{g}) on a lattice constant (a₀) for various compounds.

FIG. 7 shows calculated InₓAl₁₋ₓN/GaN QW free electron charge density, HEMT open channel drain current, threshold voltage and the barrier layer strain as a function of the In molar fraction in InAlN.

FIG. 8 shows calculated In_{0.17}Al_{0.83}N/In_{y}Ga_{1-y}N QW free electron charge density, HEMT open channel drain current, threshold voltage and the channel layer strain as a function of the In molar fraction in InGaN.

### DESCRIPTION OF THE PREFERRED EMBODIMENTS

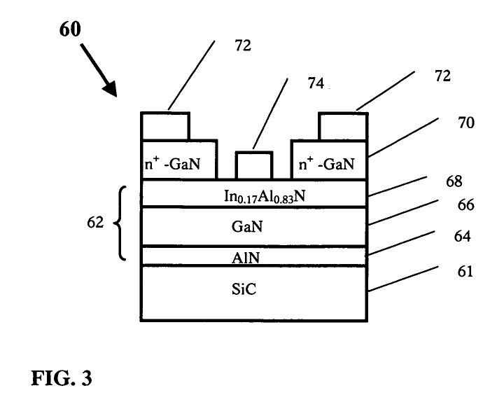

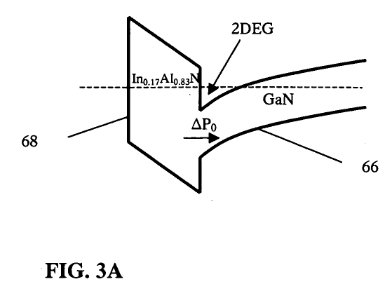

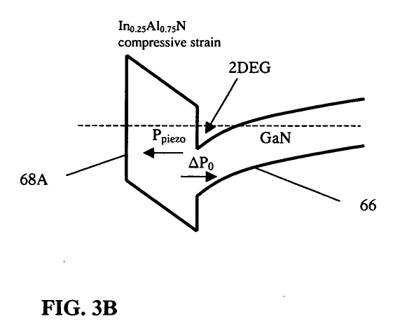

FIG. 3 illustrates a HEMT 60 according to a first preferred embodiment. HEMT 60 includes a substrate 61, a quantum well (QW) structure 62 and electrodes 72 and 74. Preferably, quantum well structure 62 includes an AlN buffer layer 64, an un-doped GaN layer 66, and an un-doped InAlN layer 68. A doped n⁺-GaN layer 70 is used to form ohmic contacts with source and drain electrodes 72.

HEMT 60 is a III-nitride HEMT fabricated on a (0001) 6H—SiC substrate 61 using molecular-beam epitaxy (MBE) or metal-organic vapor phase epitaxy (MOVPE). AlN buffer layer 64 has a thickness in the range of 10 nm to 40 nm and preferably about 20 nm. GaN layer 66 has a thickness in the range of 1 μm to 3 μm and preferably about 2 μm and the carrier concentration preferably less than about 1×10¹⁶ cm⁻³. An un-doped In_{0.17}Al_{0.83}N barrier layer 68 has a thickness in the range of about 5 nm to 30 nm, and preferably about 15 nm. The highly doped n⁺ GaN cap layer 70 has a thickness in the range of about few nm to tens of nanometers, and preferably about 15 nm and has a carrier concentration of more than 5×10¹⁸ cm⁻³. HEMT 60 has a Pt/Au gate electrode 74 and Ti/Al/Ni/Au source/drain electrodes 72.

MBE or MOVPE can be used to grow QW structure 62 on 6H—SiC substrate 61 (but other substrates such as bulk GaN crystal, 4H—SiC, sapphire, MgAl₂O₄, glass and ZnO, quartz glass, GaAs, Si may also be used as long as epitaxial growth can be achieved). Preferably, MOVPE is used to grow AlN buffer 64 at 530° C. on substrate 61 (but other buffer layers such as GaN can be used providing layers cation polarity is maintained). Next, MOVPE is continued to grow GaN layer 66 at 1000° C., while supplying a flow of ammonium gas. Precursors for Al and In are added for subsequent In and/or Al containing ternary compounds, which can be grown at about 720° C. The process provides cation-polarity epitaxial layers.

After depositing QW structure 62, HEMT 60 is fabricated using photolithography for resist patterning and subsequent mesa etching, which is necessary for device isolation. The etching is done by an electron-cyclotron resonance reactive-ion etching (ECR RIE) system using Cl₂/CH₄/H₂/Ar gas mixture. Subsequent resist patterns and lift-off are used to form ohmic contacts 72 and later Schottky contact 74. Ohmic contacts 72 (Ti/Al/Ni/Au) are placed on n⁺ GaN cap layer 70 and alloyed at 850° C. for 2 minutes. Next, n⁺-GaN cap layer 70 is RIE etched (in CH₄/H₂ gas mixture) down to In_{0.17}Al_{0.83}N barrier layer 68 through a defined resist opening. To create gate electrode 74, a Pt/Au film is vacuum evaporated. After metal has been lifted off, RIE-induced damage in the surface of In_{0.17}Al_{0.83}N barrier layer 68 is removed applying annealing at 470° C. for 40 seconds. Bonding pads made of Ti/Au are formed at the end.

FIG. 3A illustrates a band gap diagram of the In_{0.17}Al_{0.83}N/GaN QW structure 62. In QW structure 62, In_{0.17}Al_{0.83}N barrier layer 68 is lattice matched to GaN channel layer 66 and In_{0.17}Al_{0.83}N exhibits no piezoelectric polarization field. QW structure 62 exhibits high differential spontaneous polarization for the In_{0.17}Al_{0.83}N/GaN hetero-interface. Moreover, QW structure 62 does not have the negative effects related to the barrier layer relaxation.

In general, nitrides-based quantum layers exhibits piezoelectric field (P_{piezo}) and spontaneous polarization (Pₒ). Nitrides crystal structure has no inversion symmetry and consequently for strained III-nitride epitaxial layers grown in the (0001) orientation, a piezoeletric polarization will be present along the [0001] direction. The piezoelectric polarization field is given by P_{piezo}=(e₃₁−e₃₃C₃₁/C₃₃)ε₁, where e₃₁, e₃₃ are piezoeletric constants, C₃₁, C₃₃ are elastic constants, and ε₁=εₓₓ+ε_{yy} is in-plane strain. If a₀ is the lattice constant of the relaxed epitaxial layer (i.e., under no strain) and a is the lattice constant after strain has been applied (i.e., the lattice constant of the layer to which the strained layer is lattice matched), than the strain ε₁ can be calculated as ε₁=2(a−a₀)/a₀. Moreover, even if the strain is not present, nitride ionicity and structure uniaxial nature causes spontaneous polarization field P₀. The total polarization field is related to the polarization-induced charge density ρₜₒₜₐₗ according to −ρₜₒₜₐₗ∇·(P_{piezo}+P₀). In other words, the hetero-interface junction exhibits polarization sheet charge density arising from the difference ΔP₀ in spontaneous polarization between the two materials and from the change in strain that defines the P_{piezo}. The difference in polarization fields produces charge densities that may act as donors or acceptors, respectively. If at the given hetero-interface the ρₜₒₜₐₗ is positive, than free electrons with the density of nₜₒₜₐₗ=ρₜₒₜₐₗ/q, where q denotes for the electron charge, are accumulated at the hetero-interface to compensate the polarization induced charge. Similarly, a negative ρₜₒₜₐₗ can cause an accumulation of holes if the valence band edge crosses the Fermi level at the hetero-interface.

Table 1 shows values for relevant physical parameters for AlN, GaN and InN.

Spontaneous polarization field (P₀) of ternary compounds is calculated by applying Vegard's law: P₀(AₓB₁₋ₓC)=P₀(BC)+x(P₀(AC)−P₀(BC)). Vegard's law can be analogously applied for any other physical parameter listed in Tab.1. Polarization orientation is dependent on the polarity of the crystal, i.e., whether cation (Ga, Al, In) or the anion (N) bonds face the surface. Cation polarity for all materials is mostly expected for properly grown device-quality layers. The physical properties of the HEMT QW structure are important for determining transistor performance.

TABLE 1

| | AlN | GaN | InN |
|---|---|---|---|
| e₃₃ (Cm⁻²) | 1.46 | 0.73 | 0.97 |
| e₃₁ (Cm⁻²) | −0.60 | −0.49 | −0.57 |
| e₃₁ − (C₃₁/C₃₃) e₃₃ | −0.86 | −0.68 | −0.90 |
| a₀ (Å) | 3.112 | 3.189 | 3.548 |
| P₀ (Cm⁻²) | −0.081 | −0.029 | −0.032 |

The following description is based on a HEMT analytical model as described in IEEE Transactions on Electron Devices, vol. ED-30, pages 207-212, 1983 and is here modified for the polarization-induced charge to calculate the basic HEMT DC parameters. The two-dimensional gas carrier density nₛ is given by
nₛ=ε(V_{G}−V_{T})/qd (1)
where V_{G} is a gate voltage, V_{T} is a HEMT threshold voltage, ε, d are barrier layer permitivity and thickness, respectively, and q is an electron charge. We incorporate the polarization-induced charge into the calculation of V_{T} wherein the barrier layer is considered to be un-doped:
V_{T}=φ_{b}−ΔE_{C}−dₜₒₜₐₗ/ε (2)
wherein φ_{b} is a Schottky contact barrier height. A drain-to-source saturation current Iₛₐₜ can be calculated as
Iₛₐₜ=(βVₛ²(1+2βRₛV′_{G}+V′_{G}²/Vₛ²)^{1/2}−(1+βRₛV′_{G}))/(1−β²Rₛ²Vₛ²) (3)
wherein Rₛ is a parasitic source resistance and
V′_{G}=V_{G}−V_{T} (4)
Vₛ=vₛL/μ (5)
β=εμW/dL (6)
where vₛ is an electron saturation velocity, L is a gate length μ is a low field mobility of the QW electron gas and W is a gate width. Effects related to transistor self-heating are not considered in our model.

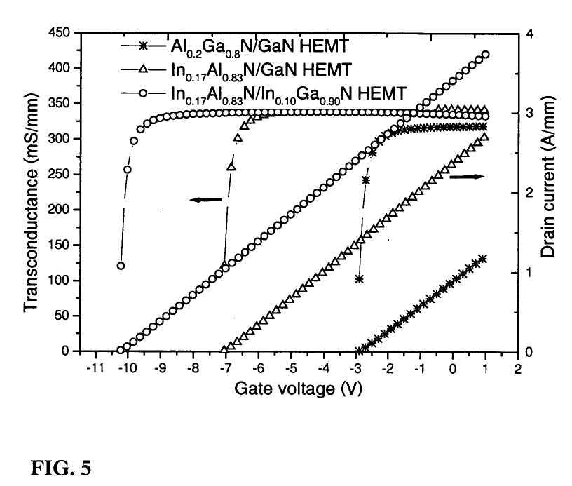

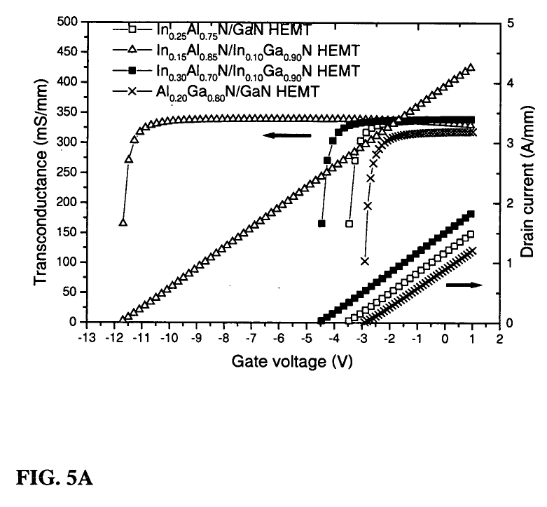

Referring again to FIG. 3A, QW structure 62 exhibits a high electron density of 2DEG due to high differential spontaneous polarization for the In_{0.17}Al_{0.83}N/GaN hetero-interface, as shown in the Table 2 below. That is, the 2DEG density is substantially higher than one would expect for any other III-V device where polarization phenomena does not dominate. In this HEMT, no extra doping is necessary to get polarization-induced charge. Importantly, QW structure 62 does not have the negative effects related to the barrier layer relaxation. This QW structure enables high current and power performance of HEMT 60, as explained in connection with FIG. 5.

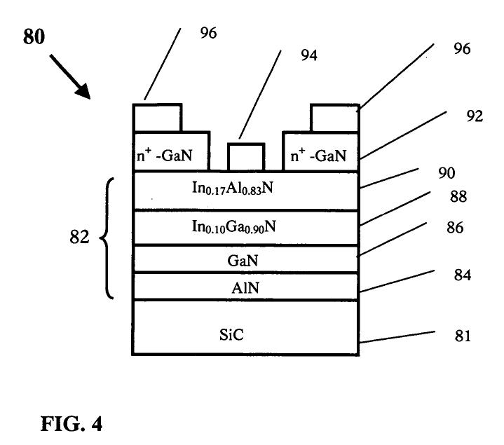

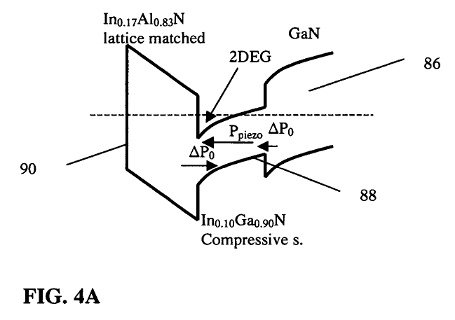

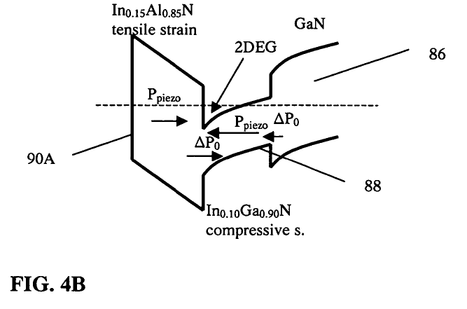

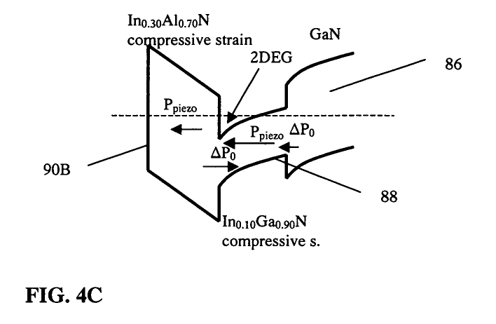

FIG. 3B illustrates a band gap diagram of another HEMT. Similarly as HEMT 60, shown in FIG. 4, HEMT 60A includes a substrate, a quantum well (QW) structure 62A and the electrodes. Quantum well structure 62A includes an AlN buffer layer, an un-doped GaN layer 66, and an un-doped InAlN layer 68A. A doped n⁺-GaN layer is used to form ohmic contacts with the source and drain electrodes. HEMT 60A has the same cross-sectional diagram as HEMT 60, shown in FIG. 3. Furthermore, HEMT 60A is fabricated using the same processing steps as HEMT 60.

In quantum well structure 62A, In_{0.25}Al_{0.75}N barrier layer 68A is compressively strained to channel layer GaN 66. The compressively strained In_{0.25}Al_{0.75}N barrier layer 68A exhibit piezoelectric field acting against the electron accumulation in the QW, as shown in FIG. 3B. Consequently, the electron density nₜₒₜₐₗ is reduced in comparison to HEMT 60, but still by 29% higher than for a AlGaN/GaN QW structure, as calculated in Tab 2. The QW structure 62A enables high current and power performance of HEMT 60A, as explained in connection with FIG. 5A.

When designing the InₓAl₁₋ₓN composition for the barrier layer at about x<0.17 the compressive strain changes to tensile strain. The corresponding piezoelectric field changes its orientation and thus increases the QW electron accumulation. On the other hand, the InₓAl₁₋ₓN composition of about x>0.25 leads to further 2DEG density decrease and thus about x=0.25 is considered as a maximal reasonable value for HEMT 60.

FIG. 4 illustrates diagrammatically a III-nitride HEMT 80 according to another embodiment. HEMT 80 includes a substrate 81, a quantum well (QW) structure 82, and electrodes 94 and 96. Preferably, quantum well structure 82 includes an AlN buffer layer 84, an un-doped GaN layer 86, an un-doped In_{0.10}Ga_{0.90}N channel layer 88, and an In_{0.17}Al_{0.83}N barrier layer 90. HEMT 80 also includes a doped n⁺-GaN layer 92 used to form ohmic contacts with source and drain electrodes 96.

In HEMT 80, reference numeral 81 denotes for a (0001) 6H—SiC substrate. AlN buffer layer 84 has a thickness in the range of about 5 μm to about 40 μm, and preferably about 20 μm, and un-doped GaN layer 86 has a thickness of about 2 μm and a carrier concentration less than about 1×10¹⁶ cm⁻³. The un-doped In_{0.10}Ga_{0.90}N channel layer 88 has a thickness in the range from few nm up to a critical thickness when relaxation appears, and preferably about 10 nm. The In_{0.17}Al_{0.83}N barrier layer 90 has a thickness in the range from about 5 nm to about 30 nm, and preferably about 15 nm. Highly doped n⁺ GaN cap layer (having a thickness in the range from about 5 nm to about 30 nm, and preferably about 15 nm and a carrier concentration in the range of 10¹⁸ cm⁻³ to 10¹⁹ cm⁻³, and preferably more than about 5×10¹⁸ cm⁻³) provides ohmic contacts to Ti/Al/Ni/Au source and drain electrodes 96. A gate electrode 94 is made of a Pt/Au film. HEMT 80 is fabricated using a similar process as described in connection with HEMT 60.

FIG. 4A illustrates a band gap diagram of the In_{0.17}Al_{0.83}N/In_{0.10}Ga_{0.90}N QW structure 82. In_{0.10}Ga_{0.90}N channel layer 88 is compressively strained between GaN layer 86 and In_{0.17}Al_{0.83}N barrier layer 90. Piezoelectric polarization field appears across channel 88. As shown in Table 2, the strain in In_{0.10}Ga_{0.90}N channel layer 88 is beneficial for further increase of the free electron density nₜₒₜₐₗ. Differential spontaneous polarization at the GaN/In_{0.10}Ga_{0.90}N hetero-interface not mentioned in the Table 2 has the value of 3×10⁻⁸ Ccm⁻² and can be neglected.

Table 2 includes physical parameters for the various heterostructures described herein. Polarization-induced QW 2DEG densities nₜₒₜₐₗ=ρₜₒₜₐₗ/q were calculated using the above theory. QW structures shown in FIGS. 3, 3A, 3B, 4, 4A, 4B and 4C exhibit high values of nₜₒₜₐₗ with highest values for QW structure made of compressively strained In_{0.10}Ga_{0.90}N channel layer 88 and tensile strained In_{0.15}Al_{0.85}N barrier layers 90A (shown and described in connection with FIG. 5B).

TABLE 2

| Heterostructure | ΔP₀ (Ccm⁻²) | P_{piezo} (Ccm⁻²) | nₜₒₜₐₗ (cm⁻²) | ΔE_{C} (eV) |
|---|---|---|---|---|
| Al_{0.2}Ga_{0.8}N/GaN | −1.04 × 10⁻⁶ | −6.9 × 10⁻⁷ | 1.08 × 10¹³ | 0.3 (0.75 ΔE_{g}) |
| In_{0.17}Al_{0.83}N/GaN | −4.37 × 10⁻⁶ | 0 | 2.73 × 10¹³ | 0.68 |
| In_{0.25}Al_{0.75}N/GaN | −3.97 × 10⁻⁶ | 1.74 × 10⁻⁶ | 1.39 × 10¹³ | 0.65 |
| In_{0.17}Al_{0.83}N/In_{0.10}Ga_{0.90}N | −4.34 × 10⁻⁶ | 1.6 × 10⁻⁶ | 3.71 × 10¹³ | >0.68 |
| In_{0.15}Al_{0.85}N/In_{0.10}Ga_{0.90}N | −4.44 × 10⁻⁶ | 1.6 × 10⁻⁶ | 4.16 × 10¹³ | >0.68 |
| | | (InGaN) | | |
| | | −6.2 × 10⁻⁷ | | |
| | | (InAlN) | | |
| In_{0.30}Al_{0.70}N/In_{0.10}Ga_{0.90}N | −3.72 × 10⁻⁶ | 1.6 × 10⁻⁶ | 1.5 × 10¹³ | >0.6 |
| | | (InGaN) | | |
| | | 2.9 × 10⁻⁶ | | |
| | | (InAlN) | | |

FIG. 4B illustrates a band gap diagram of another HEMT 80A related to HEMT 80. HEMT 80A includes a substrate, a quantum well (QW) structure 82A, and the source, drain and gate electrodes. Quantum well structure 82A includes an AlN buffer layer, an un-doped GaN layer 86, an un-doped In_{0.10}Ga_{0.90}N channel layer 88, and an In_{0.15}Al_{0.85}N barrier layer 90A. HEMT 80A also includes a doped n⁺-GaN layer used to form ohmic contacts with the source and drain electrodes, similarly as shown in FIG. 4.

Referring to FIG. 4B, in In_{0.15}Al_{0.85}N/In_{0.10}Ga_{0.90}N/GaN QW structure 82A In_{0.10}Ga_{0.90}N channel layer 88 is compressively strained to GaN layer 86. There is piezoelectric polarization field across the channel layer 88. The In_{0.15}Al_{0.85}N barrier layer 90A exhibit an additional tensile strain. Orientation of the barrier layer piezoelectric field is opposite to the In_{0.10}Ga_{0.90}N channel piezoelectric field, but points to the QW structure and causes further electron accumulation (Table 2). This QW structure enables high current and power performance of HEMT 80A, as explained in connection with FIG. 5A.

FIG. 4C illustrates a band gap diagram of another HEMT 80B related to HEMT 80. HEMT 80B includes a substrate, a quantum well (QW) structure 82B, and the source, drain and gate electrodes. Quantum well structure 82B includes an AlN buffer layer, an un-doped GaN layer 86, an un-doped In_{0.10}Ga_{0.90}N channel layer 88, and an In_{0.3}Al_{0.7}N barrier layer 90B. HEMT 80B also includes a doped n⁺-GaN layer used to form ohmic contacts with the source and drain electrodes, similarly as shown in FIG. 4.

Quantum well structure 82B has In_{0.10}Ga_{0.90}N channel layer 88 compressively strained to GaN layer 86. The piezoelectric polarization field appear across channel layer 88, as shown in FIG. 4C. The In_{0.30}Al_{0.70}N barrier layer 90B also exhibit additional compressive strain. The orientation of the barrier layer piezoelectric field is opposite the orientation in layer 90A (FIG. 4B) and causes a decrease in the electron density of 2DEG (as seen from Table 2). However, the total free electron density (nₜₒₜₐₗ) is still by about 40% higher than for AlGaN/GaN QW structure. The corresponding increase in drain current is calculated in FIG. 5A. Further increase of In molar fraction x beyond 0.30 may cause layer relaxation and thus this value can be considered as a maximal reasonable value for HEMT 80B.

FIGS. 5 and 5A displays calculated transfer and transconductance characteristics of the above-described HEMTs. The drain current (y-axis) was calculated for Iₛₐₜ using Eq. 3 together with Eqs. 1, 2, 4, 5 and 6 as a function of the HEMT gate voltage V_{G} (x-axis). The values φ_{b}=1 eV, Rₛ=1.5 Ωmm, μ=1000 cm²/Vs, vₛ=1.2×10⁵ m/s, d=15 nm were used in the calculations. The transconductance plotted on y-axis was calculated as the derivative of the drain current by the gate voltage (dIₛₐₜ/dV_{G}) and is plotted as a function of gate voltage.

Specifically, FIG. 5 displays calculated transfer and transconductance characteristics for a 200 nm gate-length of HEMTs 60 and 80 compared to prior art Al_{0.2}Ga_{0.8}N/GaN HEMT 40. High transconductance values make the HEMTs suitable for high speed applications and a high drain current density makes them suitable for high power performance.

FIG. 5A displays calculated transfer and transconductance characteristics for 200 nm gate-length of HEMTs 60A, 80A and 80B compared to prior art Al_{0.2}Ga_{0.8}N/GaN HEMT 40. The In_{0.15}Al_{0.85}N/In_{0.10}Ga_{0.90}N HEMT (HEMT 80A) exhibit a very high drain current density of about 4.2 A/mm, which represents a 255% increase compared to the AlGaN/GaN HEMT. The characteristics of In_{0.30}Al_{0.70}N/In_{0.10}Ga_{0.90}N (HEMT 80B) and In_{0.25}Al_{0.75}N/GaN (HEMT 60A) show some improved performance when compared with the AlGaN/GaN HEMT.

Theoretical characteristics in FIG. 5 show the maximum transconductance over 300 mS/mm and an open channel drain current of about 1.2 A/mm for the conventional Al_{0.2}Ga_{0.8}N/GaN HEMT. These results coincide well with already published best values for 0.15-0.2 μm gate length Al_{0.2}Ga_{0.8}N/GaN HEMTs. For In_{0.17}Al_{0.83}N/GaN HEMT 60, FIG. 5 shows only slight increase in transconductances (by about 7%) but an about 125% increase of accessible drain currents and 2.7 A/mm drain current should be accessible. Furthermore, in comparison to conventional AlGaN/GaN HEMT, In_{0.17}Al_{0.83}N/In_{0.10}Ga_{0.90}N HEMT indicates 210% current increase and 3.7 A/mm drain current density.

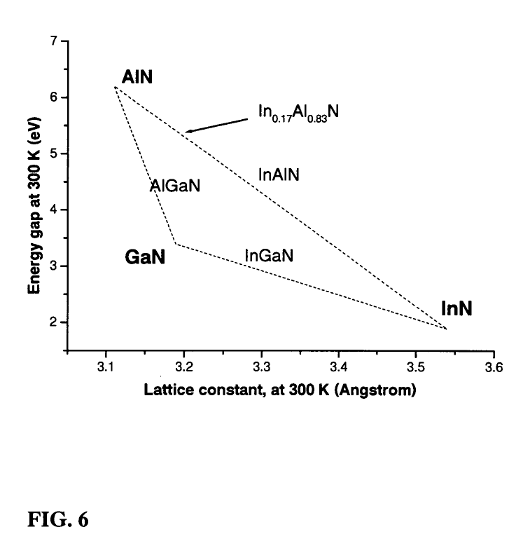

FIG. 6 depicts for various III-nitrides the dependence of energy gap (ΔE_{g}) on lattice constant (a₀) at 300 K. This dependence is useful for designing a QW structure of desired properties. For the plotted III-nitrides, the lattice constant a₀ decreases as a function of the Al molar fraction in Al nitride. Thus, to increase the carrier density (nₜₒₜₐₗ) for a AlGaN/GaN QW structure, it is suitable to increase the strain in the barrier layer by increasing the amount of Al in the AlGaN. However, a possible relaxation of the barrier layer, which diminishes piezoelectric polarization (P_{piezo}), may present a problem. Moreover, the crystallographic quality of AlGaN is decreased for higher Al molar fraction, as structural defects may appear during the growth. This can lead to poor Schottky (gate) contacts parameters. On the other hand higher piezoelectric field can be obtained for InAlN/(In)GaN QW structures even with smaller strain ε₁ if compared to conventional AlGaN/GaN. This can be seen by comparing (e₃₁−e₃₃C₃₁/C₃₃) of InₓAl₁₋ₓN and AlGa_{1-z}N for a given ε₁. The InₓAl₁₋ₓN barrier layer is superior to Al_{z}Ga_{1-z}N basically because of higher Al molar fraction in InₓAl₁₋ₓN as for Al_{z}Ga_{1-z}N with the same strain. High Al molar fraction in InₓAl₁₋ₓN is also responsible for high differential spontaneous polarization field in the InAlN/(In)GaN QW structure. Moreover, the In_{0.17}Al_{0.83}N layer can be grown lattice matched to GaN while for the AlGaN similar Al molar fraction may lead to critical lattice strain and layer relaxation can occur.

The above described HEMT 60, 60A, 80, 80A and 80B exhibit increased 2DEG density and HEMT drain current capability with a decrease in In molar fraction (x) in the barrier layer InₓAl₁₋ₓN. Electron density values as high as nₜₒₜₐₗ=4.16×10¹³ cm⁻², and drain current Iₛₐₜ=4.2 A/mm were calculated for tensile strained InₓAl₁₋ₓN, x=0.15. On the other hand, for the values of x>0.17, the strain in the barrier layer becomes compressive and for about x˜0.25-0.30 the superiority of the novel InAlN/(In)GaN type HEMTs, in comparison to prior art AlGaN/GaN HEMT 40 disappears.

Advantageously, the wide band gap of InAlN enables high breakdown voltages. Furthermore, deeper InAlN/(In)GaN QW structures improves the QW carrier confinement. Finally we conclude that InₓAl₁₋ₓN containing barrier layer provides III-nitrides HEMTs with a new quality exhibiting a record drain current/power capabilities. In HEMTs 60, 60A, 80, 80A and 80B, the high transconductance values confirm that these devices are uniquely suitable for high-frequency applications.

According to a preferred embodiment, HEMT (or HFET) devices are designed to have a maximal accumulated 2DEG in the HEMT channel. This accumulation is affected by spontaneous polarization or piezoelectric polarization or both. Regarding the charge induced by spontaneous polarization, the HEMTs (or HFETs) can be designed to have preferably the maximal difference in polarization fields keeping in mind the polarity of the layers. Based on Table 1, according to one preferred embodiment, the maximal value of ΔP₀ can be obtained for AlN/GaN or AlN/InN-based junctions. Therefore, for cation-polarity layers, the HEMTs can include a InAlN or AlGaN barrier layer on top of the (In)GaN channel, while keeping the highest possible Al molar fraction in the barrier. While a In_{0.17}Al_{0.83}N layer can be grown lattice matched to a GaN layer, a AlGaN layer with a similar Al molar fraction may lead to critical lattice strain and layer relaxation. Therefore, the preferred embodiments includes a InAlN/(In)GaN QW structure.

Regarding the charge induced by the piezoelectric polarization, the HEMTs (or HFETs) can be designed keeping in mind the layers cation-polarity. To get the highest 2DEG in the QW structure, there are the following factors regarding the barrier layer on top of the channel. The QW structure should include either a compressively strained channel layer or a tensile strained barrier layer or both. Preferably, a wide bandgap barrier layer includes InₓAl₁₋ₓN (x≦0.17) or Al_{z}Ga_{1-z}N (0≦z≦1), while the channel includes In_{y}Ga_{1-y}N (0≦y≦1). The piezoelectric polarization is calculated as follows: P_{piezo}=(e₃₁−e₃₃C₃₁/C₃₃)ε₁ where e₃₁, e₃₃ are piezoeletric constants, C₃₁, C₃₃ are elastic constants and ε₁=εₓₓ+ε_{yy} is in-plane strain. Therefore, for a maximal acceptable strain (i.e., ε₁ can be further considered as a constant), a very important factor is represented by the value of (e₃₁−e₃₃C₃₁/C₃₃), which should be also maximal. When comparing the value of (e₃₁−e₃₃C₃₁/C₃₃). for InₓAl₁₋ₓN and Al_{z}Ga_{1-z}N, for given ε₁ the InₓAl₁₋ₓN barrier layer is again preferred over Al_{z}Ga_{1-z}N basically because of higher Al molar fraction in InₓAl₁₋ₓN as for Al_{z}Ga_{1-z}N with the same strain. These rules can be applied to other types of materials when designing a QW structure.

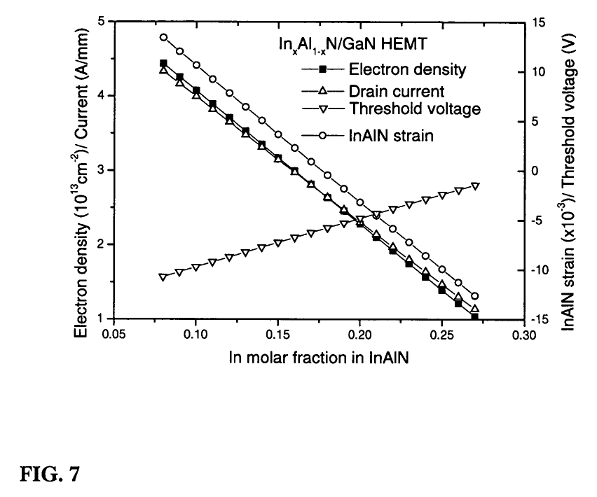

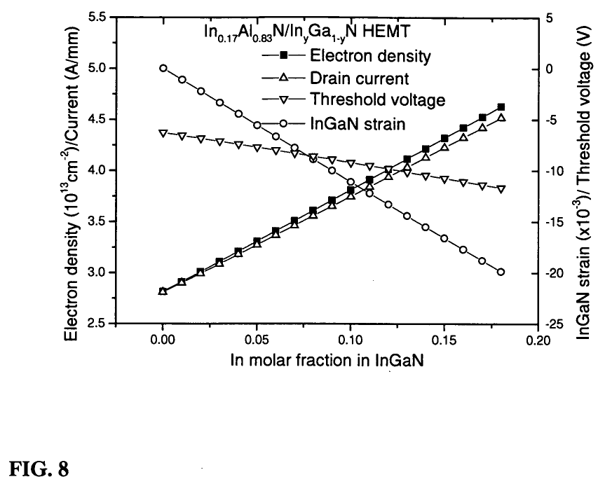

In FIGS. 7 and 8 we show calculated QW free electron density nₜₒₜₐₗ, HEMT open channel drain current and threshold voltage as well as strain as a function of In molar fraction in InₓAl₁₋ₓN/GaN or In_{0.17}Al_{0.83}N/In_{y}Ga_{1-y}N QW structures, respectively. As indicated by the right y-axes scales, critical (maximal) acceptable strain for 15 nm thick InAlN (FIG. 7) and 5-10 nm thick InGaN (FIG. 8) was estimated to be 0.0125 and 0.02, respectively.

According to another embodiment, the above described HEMT 60, 60A, 80, 80A and 80B may also be created by engineering the bandgap profile of the barrier layer, i.e., step-wise changing or continuously decreasing the Al molar fraction in the InAlN barrier layer. These types of HEMTs exhibit a significantly decreased source resistance. U.S. Pat. No. 6,064,082 to Kawai, et al. (incorporated by reference) discloses a variation in the bandgap profile by changing the barrier layer. Kawai continuously decreased the Al molar fraction in the AlGaN barrier layer in direction to the contact layer. The transistor of Kawai however does not involve the polarization phenomena used in the above-described HEMTs, nor suggests using of InAlN based barrier layer.

According to yet another embodiment, the above-described HEMTs 60, 60A, 80, 80A and 80B may also be created by forming a multi-layered channel structure. A multi-layered channel structure was used in a nitride-type III-V group HEMT described in U.S. Pat. No. 6,177,685. This HEMT uses a channel layer with a multi-layered structure containing InN, which according to the U.S. Pat. No. 6,177,685 patent, provides an increased 2DEG mobility in the HEMT channel. The above-described HEMTs 60, 60A, 80, 80A and 80B may also use a InN/GaN multi-layered structure in the channel in addition to the InAlN in place of the barrier layer. However, U.S. Pat. No. 6,177,685 does not disclose or even suggest using InAlN in place of the barrier layer or specifically envisions the use of the polarization phenomena.

According to yet another embodiment, the above-described HEMTs 60, 60A, 80, 80A and 80B may also be fabricated by using a doped layer in the QW structure. In this case, both the polarization phenomena and impurity doping affects the 2DEG layer formed in the HEMT channel.

In general, possible applications include transmissions from Direct Broadcast Satellites (DBS) operating at about 12 GHz (but generally any communication system operating at frequencies in the range of 1 GHz to 400 GHz). A DBS outdoor receiver unit includes RF amplifier and filter, mixer, intermediate frequency amplifier and local oscillator. Other applications include cellular radio and radar applications such as radars for vehicle collision avoidance. Monolithic microwave or millimeter wave integrated circuits (MMICs) may also find application in instrumentation, for example, in frequency synthesizers, network analyzers, spectrum analyzers and sampling oscilloscopes.

Furthermore, the above described HEMTs may also be used in radars with electronically-steerable beams, known as phase-arrays, MMIC amplifiers, mixers, MMIC RF drivers, and MMIC phase shifters, or any other devices that require a high-frequency operation (1 GHz to 400 GHz), high power, low noise, or any combination thereof.

In short, the above-described HEMTs 60, 60A, 80, 80A and 80B are suitable for high frequency and high power applications such as needed for portable phones, satellite broadcasting, satellite communication systems, land-based communication systems (see IEEE Spectrum, Vol. 39 (2002), No. 5, pp. 28-33) and other systems that use high-frequency waves such as microwaves or millimeter waves. In these systems, high-power amplifiers (preferably having low noise) are used for amplification or signal transmission.

Specifically, the above-described HEMTs 60, 60A, 80, 80A and 80B are suitable for use in portable telephones such as the portable telephones disclosed in U.S. Pat. No. 6,172,567, which is incorporated by reference. The above-described HEMTs 60, 60A, 80, 80A and 80B are also suitable for use in communication systems, such as the communication systems disclosed in U.S. Pat. No. 6,263,193 or U.S. Pat. No. 6,259,337, both of which are incorporated by reference. The above-described HEMTs 60, 60A, 80, 80A and 80B are suitable for use in direct broadcast satellite systems such as the direct broadcast satellite system s disclosed in U.S. Pat. No. 5,649,312 or U.S. Pat. No. 5,940,750, both of which are incorporated by reference.

The above-described HEMTs 60, 60A, 80, 80A and 80B are suitable for construction of low noise amplifiers (LNAs). These amplifiers are optimized for minimum noise and are used in receiver front ends, for example, in wireless telecommunications, radar sensors, and in IF amplifiers for radioastronomy receivers. HEMTs 60, 60A, 80, 80A and 80B may be used for construction of low noise amplifiers such as the noise amplifiers disclosed in U.S. Pat. No. 5,933,057 or U.S. Pat. No. 5,815,113, both of which are incorporated by reference. Furthermore, HEMTs 60, 60A, 80, 80A and 80B may be used for construction of intermediate frequency amplifiers such as the intermediate frequency amplifiers disclosed in U.S. Pat. No. 5,528,769 or U.S. Pat. No. 5,794,133, both of which are incorporated by reference. Furthermore, HEMTs 60, 60A, 80, 80A and 80B are suitable for construction of power amplifiers such as the power amplifiers disclosed in U.S. Pat. No. 6,259,337 or U.S. Pat. No. 6,259,335, both of which are incorporated by reference.

Furthermore, the above-described HEMTs 60, 60A, 80, 80A and 80B are suitable for use in radar systems such as the radar systems disclosed in U.S. Pat. No. 6,137,434 or in U.S. Pat. No. 6,094,158, both of which are incorporated by reference. Other likely applications of the above-described HEMTs 60, 60A, 80, 80A and 80B include high performance radar units and LMDS (Local Multipoint Distribution Service) “wireless fiber” broadband links being developed for operation at 28 GHz and 31 GHz, which is incorporated by reference for all purposes.

Furthermore, the above-described HEMTs 60, 60A, 80, 80A and 80B are suitable for construction of sensor systems such as the sensor systems disclosed in U.S. Pat. No. 6,104,075 or U.S. Pat. No. 5,905,380, both of which are incorporated by reference.

The above-described HEMTs 60, 60A, 80, 80A and 80B can be fabricated on and incorporated in monolithic microwave or millimeter wave integrated circuits (MMICs). These circuits include voltage controlled oscillators at selected discrete frequencies up to 350 GHz, low-noise amplifiers at selected frequencies in the range of 1 GHz and 350 GHz or frequency ranges (generally selected frequencies from 1 GHz up to 400 GHz), phase shifters, and resistive and active mixers at frequencies in the range of 1 GHz up to 250 GHz (and even 350 GHz or 400 GHz). The above-described HEMTs 60, 60A, 80, 80A and 80B can be fabricated on and incorporated in GaN-based MMIC attenuators (see E. Alekseev, Broadband AlGaN/GaN HEMT MMIC Attenuators with High Dynamic Range, 30^{th} European Microwave Conference, Paris, October 2000) using HEMTs broadband and high-dynamic range characteristics and very high power handling, which is incorporated by reference for all purposes.

The above-described HEMTs 60, 60A, 80, 80A and 80B may be used in various hybrid circuits and systems. For example, instead of building a complete transceiver MMIC system from the monolithic components described above, the HEMTs are used in hybrid systems (MMIC systems would require circuits that are too large and expensive to be created on a single substrate). One negative side effect of using transmission line matching networks is that they use a lot of chip area for purely passive elements. Microstrip circuits for mm-wave applications using discrete HEMTs or individual monolithic circuits can reduce the system cost massively. These may be mounted next to other discrete devices upside-down onto a dielectric microstrip circuit using various packaging techniques such as flip-chip bonding using gold-bumps.

The present invention was described with reference to the above aspects and embodiments, but the invention is by no means limited to the particular embodiments described herein and/or shown in the drawings, alone or in combination with the above-cited publications (all of which are incorporated by reference). The present invention also comprises any modifications or equivalents within the scope of the following claims.

1. A hetero-interface field effect transistor comprising:
a substrate; and
a cation-polarity layered structure including at least a barrier layer and a channel layer wherein said barrier layer includes InₓAl₁₋ₓN, x being in the range of about 0≦x≦0.30.

2. The hetero-interface field-effect transistor according to claim 1 wherein said barrier layer includes In_{0.17}Al_{0.83}N

3. The hetero-interface field-effect transistor according to claim 2 wherein said channel layer includes GaN

4. The hetero-interface field-effect transistor according to claim 2 wherein said channel layer includes In_{y}Ga_{1-y}N, y being in the range of about 0≦y≦1.

5. The hetero-interface field-effect transistor according to claim 1 wherein said barrier layer includes InₓAl₁₋ₓN, x being in the range of about 0≦x≦0.17.

6. The hetero-interface field-effect transistor according to claim 5 wherein said channel layer includes GaN

7. The hetero-interface field-effect transistor according to claim 5 wherein said channel layer includes In_{y}Ga_{1-y}N (0<y≦1).

8. The hetero-interface field-effect transistor according to claim 1 wherein said barrier layer includes InₓAl₁₋ₓN, x being in the range of about 0.17<x≦0.25

9. The hetero-interface field-effect transistor according to claim 8 wherein said channel layer includes GaN.

10. The hetero-interface field-effect transistor according to claim 8 wherein said channel layer includes In_{y}Ga_{1-y}N, y being in the range of about 0<y≦1.

11. The hetero-interface field-effect transistor according to claim 1 wherein said barrier layer includes InₓAl₁₋ₓN, x being in the range of about 0.25<x≦0.30.

12. The hetero-interface field-effect transistor according to claim 11 wherein said channel layer includes In_{y}Ga_{1-y}N, x being in the range of about 0<y≦1.

13. A hetero-interface field effect transistor comprising:
a substrate; and
a layered QW structure including at least a barrier layer in contact with a channel layer providing the total two dimensional electron gas density of above nₜₒₜₐₗ=1.1×10¹³ cm⁻².

14. The hetero-interface field-effect transistor according to claim 13 wherein said channel layer is in contact with a layer grown to provide cation polarity of said barrier layer and said channel layer exhibiting polarization induced charge and wherein said barrier layer includes InₓAl₁₋ₓN, x being in the range of about 0≦x<0.17.

15. The hetero-interface field-effect transistor according to claim 14 wherein said channel layer includes GaN.

16. The hetero-interface field-effect transistor according to claim 14 wherein said channel layer includes In_{y}Ga_{1-y}N (0<y≦1).

17. The hetero-interface field-effect transistor according to claim 13 wherein said channel layer is in contact with a layer grown to provide cation polarity of said barrier layer and said channel layer exhibiting polarization induced charge, and wherein said barrier layer includes InₓAl₁₋ₓN, x being in the range of about 0.17<x≦0.25

18. A method for fabricating a hetero-interface field effect transistor comprising:
providing a substrate; and
fabricating a layered QW structure including at least a barrier layer and a channel layer providing the total two dimensional electron gas density of above nₜₒₜₐₗ=1.1×10¹³ cm⁻².

19. A method for fabricating a hetero-interface field effect transistor comprising:
providing a substrate; and
fabricating a layered QW structure including at least a barrier layer and a channel layer wherein barrier layer includes InₓAl₁₋ₓN where 0≦x≦0.30.
